(19) United States
(12) Patent Application Publication
(10) Pub. No.: US 2026/0201202 A1
(43) Pub. Date: Jul. 16, 2026

(54) METHODS OF MANUFACTURING SEMICONDUCTOR DEVICE AND COATING COMPOSITIONS

(71) Applicant: Taiwan Semiconductor Manufacturing Company, Ltd., Hsinchu (TW)

(72) Inventors: Jia-Lin WEI, Hsinchu (TW); Lilin CHANG, Hsinchu (TW); Yahru CHENG, Hsinchu (TW)

(73) Assignee: Taiwan Semiconductor Manufacturing Company, Ltd., Hsinchu (TW)

(21) Appl. No.: 19/021,760

(22) Filed: Jan. 15, 2025

(51) Int. Cl. C09D 167/00; G03F 7/11; G03F 7/16; H01L 21/308; H01L 21/311; H01L 21/3213

(52) U.S. Cl. CPC C09D 167/00; G03F 7/11; G03F 7/162; H10P 50/692; H10P 50/71; H10P 50/73

(57) ABSTRACT

A method of manufacturing a semiconductor device includes depositing a coating composition on a patterned surface of a photoresist layer and curing the coating composition on the patterned photoresist layer. The coating composition includes a block copolymer including a first moiety configured to chemically bond with the patterned surface of the patterned photoresist layer and a second moiety including a mesogenic structure. The mesogenic structure is configured to exhibit liquid crystal properties upon curing the coating composition.

### BACKGROUND

With the development of electronic devices, increasingly smaller electronic components (e.g., transistors, resistors, capacitors, etc.) have been developed over time. In some cases, photolithography is used to fabricate semiconductor devices including small components. In photolithography processes, photosensitive material is applied to a surface to be patterned and then exposed to a pattern of energy. The exposure modifies the chemical and physical properties of the exposed regions of the photosensitive material. The difference in material characteristics between exposed and unexposed regions of the photosensitive material can be exploited to remove one region without removing the other, and vice-versa.

However, with pressure to further decrease the size of electronic devices, the processing windows for photolithographic processing have become smaller. Advances in the field of photolithographic processing are sought to maintain the ability to scale down the devices and meet the design criteria.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a process stage of a sequential operation according to an embodiment of the disclosure.

FIG. 3 shows a process stage of a sequential operation according to an embodiment of the disclosure.

FIG. 4 shows a process stage of a sequential operation according to an embodiment of the disclosure.

FIG. 5A shows a process stage of a sequential operation according to an embodiment of the disclosure.

FIG. 5B shows a process stage of a sequential operation according to an embodiment of the disclosure.

FIG. 5C shows a process stage of a sequential operation according to an embodiment of the disclosure.

FIG. 5D schematically illustrates a coating composition applied to a photoresist according to an embodiment of the disclosure.

FIG. 6 shows a process stage of a sequential operation according to an embodiment of the disclosure.

FIG. 7 shows a process stage of a sequential operation according to an embodiment of the disclosure.

FIG. 8 shows a process stage of a sequential operation according to an embodiment of the disclosure.

FIG. 9 shows a process stage of a sequential operation according to an embodiment of the disclosure.

FIG. 10A shows a process stage of a sequential operation according to an embodiment of the disclosure.

FIG. 10B shows a process stage of a sequential operation according to an embodiment of the disclosure.

FIG. 10C shows a process stage of a sequential operation according to an embodiment of the disclosure.

FIG. 11 shows a process stage of a sequential operation according to an embodiment of the disclosure.

FIG. 12 shows a process stage of a sequential operation according to an embodiment of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

It has been discovered that a coating composition containing a block copolymer including a mesogenic structure can be applied to a patterned photoresist layer. Upon curing the coating composition on the patterned photoresist layer, the cured coating can improve one or more of the smoothness and hardness of the surface of the patterned photoresist, which can improve the etching performance of the patterned photoresist. For example, the patterned photoresist layer covered with the cured coating can improve the precision in forming structures having high local critical dimension uniformity (LCDU) and reduced wiggling, as measured with a critical dimension scanning electron microscope (CDSEM). The cured coating can also improve precision when measured with cross-sectional transmission electron microscopy (TEM). The cured coating can also yield improved precision when etching at fine pitches, as measured with injection level spectroscopy (ILS).

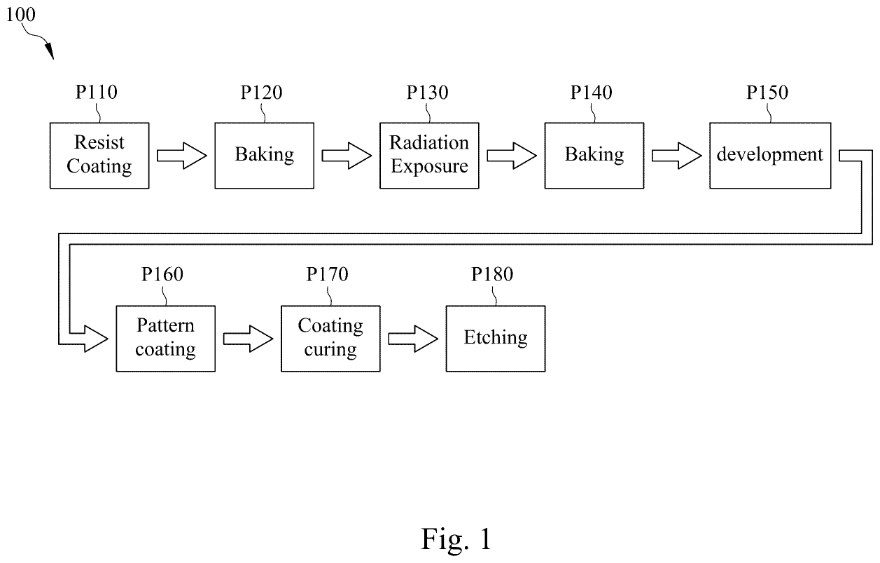

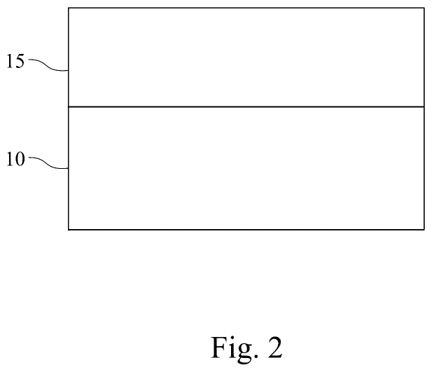

FIG. 1 illustrates a process flow 100 of manufacturing a semiconductor device according to embodiments of the disclosure. A photoresist is coated on a surface of a layer to be patterned or a substrate 10 in operation P110, in some embodiments, to form a photoresist layer 15, as shown in FIG. 2. Then the photoresist layer 15 undergoes a first baking operation P120 to evaporate solvents in the photoresist composition in some embodiments. The photoresist layer 15 is baked at a temperature and time sufficient to cure and dry the photoresist layer 15. In some embodiments, the photoresist layer is heated to a temperature of about 40° C. to about 250° C. for about 10 seconds to about 10 minutes.

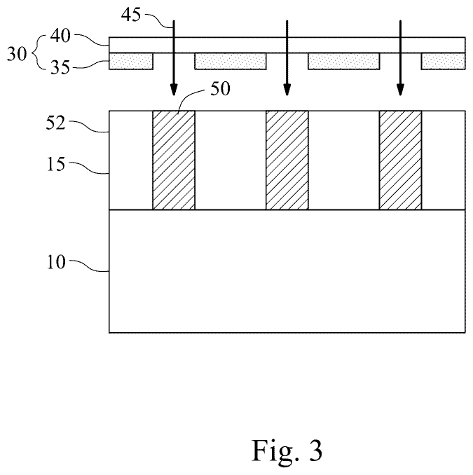

After the first baking operation P120, the photoresist layer 15 is selectively exposed to actinic radiation 45 (see FIG. 3) in operation P130. In some embodiments, the photoresist layer 15 is selectively exposed to ultraviolet radiation. In some embodiments, the ultraviolet radiation is deep ultraviolet radiation. In some embodiments, the ultraviolet radiation is extreme ultraviolet (EUV) radiation. In some embodiments, the radiation is an electron beam.

As shown in FIG. 3, the exposure radiation 45 passes through a photomask 30 before irradiating the photoresist layer 15 in some embodiments. In some embodiments, the photomask has a pattern to be replicated in the photoresist layer 15. The pattern is formed by an opaque pattern 35 on photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

The region 50 of the photoresist layer exposed to radiation undergoes a chemical reaction thereby changing its solubility in a subsequently applied developer relative to the region 52 of the photoresist layer not exposed to radiation. In some embodiments, the region 50 of the photoresist layer exposed to radiation undergoes a crosslinking reaction.

Next, the photoresist layer 15 undergoes a post-exposure bake in operation P140. In some embodiments, the photoresist layer 15 is heated to a temperature of about 50° C. to about 160° C. for about 20 seconds to about 120 seconds. The post-exposure baking may be used in order to assist in the generating, dispersing, and reacting of the acid/base/free radical generated from the impingement of the radiation 45 upon the photoresist layer 15 during the exposure. Such assistance helps to create or enhance chemical reactions which generate chemical differences between the exposed region 50 and the unexposed region 52 within the photoresist layer. These chemical differences also caused differences in the solubility between the exposed region 50 and the unexposed region 52.

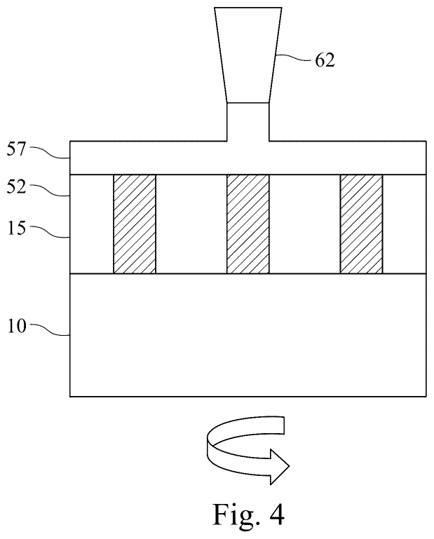

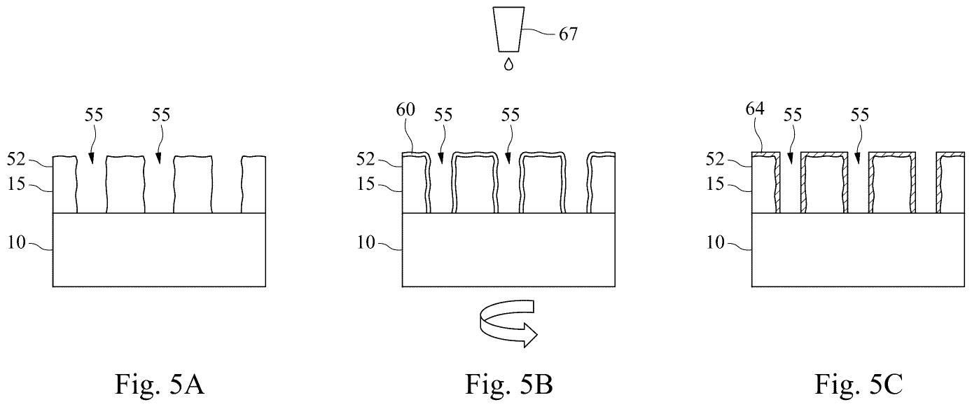

The selectively exposed photoresist layer is subsequently developed by applying a developer to the selectively exposed photoresist layer in operation P150. As shown in FIG. 4, a developer 57 is supplied from a dispenser 62 to the photoresist layer 15 according to an embodiment. In some embodiments, the exposed region 50 of the photoresist layer is removed by the developer 57 forming a pattern of openings 55 in the photoresist layer 15 to expose the substrate 10, as shown in FIG. 5A. FIG. 5A schematically illustrates that the patterned surfaces of the photoresist layer 15 exhibit a surface roughness. The surface roughness can adversely affect the precision of etching processes using the patterned surface as an etching mask. It has been discovered that a patterned photoresist layer can be coated with a coating composition containing a copolymer including a liquid crystal moiety and then cured. The cured coating composition can improve one or more of the smoothness and hardness of the surface of the patterned photoresist, which can improve the etching performance of the patterned photoresist.

FIG. 5B illustrates an embodiment of a dispenser 67 applying a coating composition 60 containing a copolymer including a liquid crystal moiety to the photoresist layer 15 of FIG. 5A. FIG. 5C illustrates an embodiment of a cured coating 64 obtained by curing the coating composition 60 shown in FIG. 5B. The cured coating 64 improves the smoothness of the patterned surfaces of the photoresist layer 15.

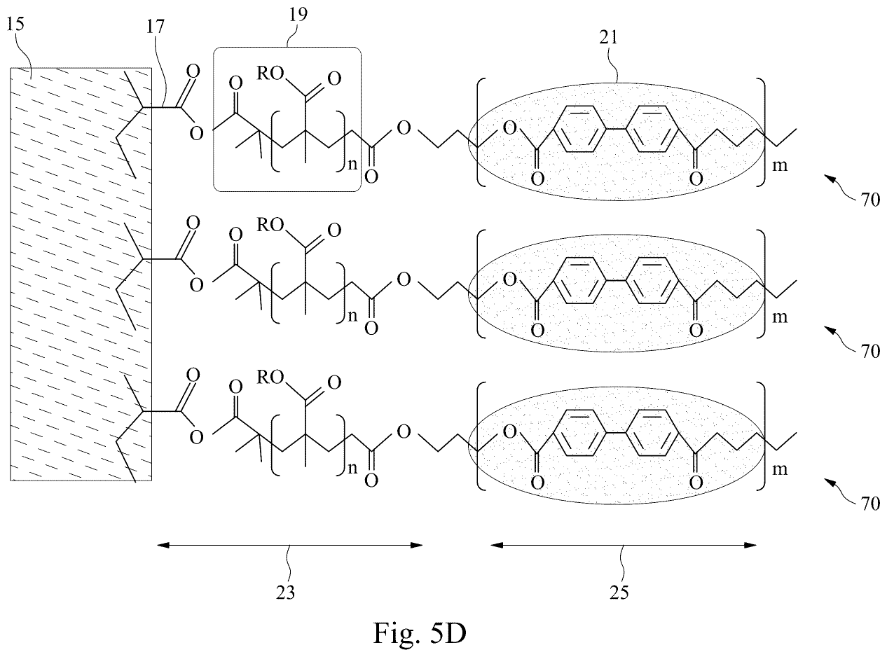

In some embodiments, an etching process is used to transfer the pattern of the openings 55 in the photoresist layer 15 covered by the cured coating 64 into the substrate 10 and/or one or more intermediate layers between the substrate and the patterned photoresist layer, to create a pattern of openings 55′ as shown in FIG. 6. The pattern can be extended into the substrate and/or the one or more intermediate layers using one or more suitable etching processes such as dry etching or wet etching. The unexposed photoresist layer 15 and cured coating 64 are at least partially removed during the etching operation in some embodiments. In other embodiments, the unexposed photoresist layer 15 and cured coating 64 are removed after etching the substrate 10 by using a suitable photoresist stripper solvent or by a photoresist ashing operation.

In some embodiments, the substrate 10 includes a single crystalline semiconductor layer on at least a surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes at least one metal, metal alloy, and metal nitride/sulfide/oxide/silicide having the formula MXa, where Mis a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, and combinations thereof.

In some embodiments, the substrate 10 includes a dielectric having at least silicon, metal oxide, and metal nitride of the formula MXb, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, and combinations thereof.

The photoresist layer 15 is a photosensitive layer that is patterned by exposure to actinic radiation. Typically, the chemical properties of the photoresist regions struck by incident radiation change in a manner that depends on the type of photoresist used. Photoresist layers 15 are typically positive resists or negative resists. Conventionally, positive resist refers to a photoresist material that when exposed to radiation (typically UV light) becomes soluble in a developer, while the region of the photoresist that is non-exposed (or exposed less) is insoluble in the developer. Negative resist, on the other hand, conventionally refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

Whether a resist is a positive or negative resist may depend on the type of developer used to develop the resist. For example, some positive photoresists provide a positive pattern, (i.e.—the exposed regions are removed by the developer), when the developer is an aqueous-based developer, such as a tetramethylammonium hydroxide (TMAH) solution. On the other hand, the same photoresist provides a negative pattern (i.e.—the unexposed regions are removed by the developer) when the developer is an organic solvent. Further, in some negative photoresists developed with the TMAH solution, the unexposed regions of the photoresist are removed by the TMAH, and the exposed regions of the photoresist, that undergo cross-linking upon exposure to actinic radiation, remain on the substrate after development. In some embodiments, a negative photoresist is exposed to actinic radiation. The exposed portions of the negative photoresist undergo crosslinking as a result of the exposure to actinic radiation, and during development the exposed, crosslinked portions of the photoresist are removed by the developer leaving the unexposed regions of the photoresist remaining on the substrate.

In an embodiment, the photoresist layer 15 is a negative photoresist that undergoes a cross-linking reaction upon exposure to the radiation. In some embodiments, a photoresist includes a polymer resin along with one or more photoactive compounds (PACs) in a solvent. In some embodiments, the polymer resin includes a hydrocarbon structure (such as an alicyclic hydrocarbon structure) that contains one or more groups that will decompose (e.g., acid labile groups) or otherwise react when mixed with acids, bases, or free radicals generated by the PACs (as further described below). In some embodiments, the hydrocarbon structure includes a repeating unit that forms a skeletal backbone of the polymer resin. This repeating unit may include one or more of an acrylic ester, a methacrylic ester, a crotonic ester, a vinyl ester, a maleic diester, a fumaric diester, an itaconic diester, a (meth)acrylonitrile, a (meth)acrylamide, a styrene, a vinyl ether, a phenol, or the like. In some embodiments, phenol repeating units form novolac structures, cresol structures, resol structures. In an embodiment, a photoresist includes one or more of a phenol novolac resin, a cresol resin, or a resol resin.

In some embodiments, examples of structures for preparing units of a polymer of a polymer resin include one or more of methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, butyl crotonate, hexyl crotonate, vinyl acetate, vinyl propionate, vinyl butylate, vinyl methoxyacetate, vinyl benzoate, dimethyl maleate, diethyl maleate, dibutyl maleate, dimethyl fumarate, diethyl fumarate, dibutyl fumarate, dimethyl itaconate, diethyl itaconate, dibutyl itaconate, acrylamide, methyl acrylamide, ethyl acrylamide, propyl acrylamide, n-butyl acrylamide, tert-butyl acrylamide, cyclohexyl acrylamide, 2-methoxyethyl acrylamide, dimethyl acrylamide, diethyl acrylamide, phenyl acrylamide, benzyl acrylamide, methacrylamide, methyl methacrylamide, ethyl methacrylamide, propyl methacrylamide, n-butyl methacrylamide, tert-butyl methacrylamide, cyclohexyl methacrylamide, 2-methoxyethyl methacrylamide, dimethyl methacrylamide, diethyl methacrylamide, phenyl methacrylamide, benzyl methacrylamide, methyl vinyl ether, butyl vinyl ether, hexyl vinyl ether, methoxyethyl vinyl ether, dimethylaminoethyl vinyl ether, styrene, methyl styrene, dimethyl styrene, trimethyl styrene, ethyl styrene, isopropyl styrene, butyl styrene, methoxy styrene, butoxy styrene, acetoxy styrene, chloro styrene, dichloro styrene, bromo styrene, vinyl methyl benzoate, α-methyl styrene, maleimide, vinylpyridine, vinylpyrrolidone, vinylcarbazole, phenol, pyrocatechol, resorcinol, hydroquinone, napthol, cresol, or the like.

In some embodiments, a repeating unit also has either a monocyclic or a polycyclic hydrocarbon structure substituted into it, or the monocyclic or polycyclic hydrocarbon structure is the repeating unit, in order to form an alicyclic hydrocarbon structure. In some embodiments, a polymer includes a monocyclic structure, or polycyclic structures such as bicycloalkane, tricycloalkane, tetracycloalkane, cyclopentane, cyclohexane, or the like. In some embodiments, a polymer or a polymer resin includes one or more polycyclic structures such as adamantane, norbornane, isobornane, tricyclodecane, tetracyclododecane, or the like. In some embodiments, a polymer or a polymer resin includes one or more polyaromatic structure, a combination including a polyaromatic structure and an alicyclic structure, a combination including a polyaromatic structure and an aliphatic structure, or a combination including a polyaromatic structure, an alicyclic structure, and an aliphatic structure.

As noted above, a polymer or polymer resin can include one or more groups that will decompose. The group which will decompose, otherwise known as a protecting group or a leaving group or, in some embodiments in which the PAC is a photoacid generator, an acid labile group, is attached to the polymeric structure so that, it will react with the acids/bases/free radicals generated by the PACs during exposure to radiation. In some embodiments, the group which will decompose is a carboxylic acid group, an ester group, a fluorinated alcohol group, a phenolic alcohol group, a sulfonic group, a sulfonamide group, a sulfonylimido group, an (alkylsulfonyl)(alkylcarbonyl)methylene group, an (alkylsulfonyl)(alkyl-carbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl methylene group, a tris(alkylsulfonyl)methylene group, combinations of these, or the like. Specific groups that are used for the fluorinated alcohol group include fluorinated hydroxyalkyl groups, such as a hexafluoroisopropanol group in some embodiments. Specific groups that are used for the carboxylic acid group include acrylic acid groups, methacrylic acid groups, or the like.

In some embodiments, the polymer resin also includes other groups attached to the polymeric structure that help to improve a variety of properties of the polymerizable resin. For example, inclusion of a lactone group to the polymeric structure assists to reduce the amount of line edge roughness after the photoresist has been developed, thereby helping to reduce the number of defects that occur during development. In some embodiments, the lactone groups include rings having five to seven members, although any suitable lactone structure may alternatively be used for the lactone group.

In some embodiments, the polymer resin includes groups that can assist in increasing the adhesiveness of the photoresist layer 15 to underlying structures (e.g., substrate 10). Polar groups may be used to help increase the adhesiveness. Suitable polar groups include hydroxyl groups, cyano groups, or the like, although any suitable polar group may, alternatively, be used.

Optionally, the polymer resin includes one or more alicyclic structures that do not also contain a group which will decompose in some embodiments. In some embodiments, the structure that does not contain a group which will decompose includes structures such as 1-adamantyl (meth)acrylate, tricyclodecanyl (meth)acrylate, cyclohexyl (methacrylate), combinations of these, or the like.

Additionally, some embodiments of the photoresist include one or more PACs, such as photoacid generators, photobase generators, free-radical generators, or the like. The PACs may be positive-acting or negative-acting. In some embodiments in which the PACs are a photoacid generator, the PACs include one or more of halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, or the like.

In some embodiments, a photoacid generator includes one or more of α-(trifluoro methylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoro antimonates, hexafluoroarsenates, trifluoromethanesulfonates, iodonium perfluoro octanesulfonate, N-camphorsulfonyloxynaphthalimide, N-pentafluorophenyl sulfonyl oxynaphthalimide, ionic iodonium sulfonates such as diaryl iodonium (alkyl or aryl) sulfonate and bis-(di-t-butylphenyl) iodonium camphanylsulfonate, perfluoro alkanesulfonates such as perfluoropentanesulfonate, perfluorooctanesulfonate, perfluoro methanesulfonate, aryl (e.g., phenyl or benzyl)triflates such as triphenylsulfonium triflate or bis-(t-butylphenyl) iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, or the like.

In some embodiments in which the PACs are free-radical generators, the PACs include one or more of n-phenylglycine; aromatic ketones, including benzophenone, N,N′-tetramethyl-4,4′-diaminobenzophenone, N,N′-tetraethyl-4,4′-diaminobenzophenone, 4-methoxy-4′-dimethylaminobenzo-phenone, 3,3′-dimethyl-4-methoxybenzophenone, p,p′-bis(dimethylamino) benzophenone, p,p′-bis(diethylamino)-benzophenone; anthraquinone, 2-ethylanthraquinone; naphthaquinone; and phenanthraquinone; benzoins including benzoin, benzoinmethylether, benzoinisopropylether, benzoin-n-butylether, benzoin-phenylether, methylbenzoin and ethyl benzoin; benzyl derivatives, including dibenzyl, benzyldiphenyldisulfide, and benzyl dimethyl ketal; acridine derivatives, including 9-phenylacridine, and 1,7-bis(9-acridinyl) heptane; thioxanthones, including 2-chlorothioxanthone, 2-methylthioxanthone, 2,4-diethyl thioxanthone, 2,4-dimethylthioxanthone, and 2-isopropylthioxanthone; acetophenones, including 1,1-dichloro acetophenone, p-t-butyldichloro-acetophenone, 2,2-diethoxyacetophenone, 2,2-dimethoxy-2-phenylacetophenone, and 2,2-dichloro-4-phenoxyacetophenone; 2,4,5-triaryl imidazole dimers, including 2-(o-chlorophenyl)-4,5-diphenylimidazole dimer, 2-(o-chloro phenyl)-4,5-di-(m-methoxyphenyl) imidazole dimer, 2-(o-fluorophenyl)-4,5-diphenyl imidazole dimer, 2-(o-methoxyphenyl)-4,5-diphenylimidazole dimer, 2-(p-methoxy phenyl)-4,5-diphenyl imidazole dimer, 2,4-di(p-methoxyphenyl)-5-phenylimidazole dimer, 2-(2,4-dimethoxyphenyl)-4,5-diphenylimidazole dimer, 2-(p-methylmercaptophenyl)-4,5-diphenylimidazole dimer, or the like.

In some embodiments in which the PACs are photobase generators, the PACs includes one or more of quaternary ammonium dithiocarbamates, α aminoketones, oxime-urethane containing molecules such as dibenzophenoneoxime hexamethylene diurethan, ammonium tetraorganylborate salts, and N-(2-nitrobenzyloxycarbonyl) cyclic amines, or the like.

As one of ordinary skill in the art will recognize, the chemical compounds listed herein are merely intended as illustrated examples of the PACs and are not intended to limit the embodiments to only those PACs specifically described. Rather, any suitable PAC may be used, and all such PACs are fully intended to be included within the scope of the present embodiments.

In some embodiments, a cross-linking agent is added to the photoresist. The cross-linking agent reacts with one group from one of the polymeric structures in the polymer resin and also reacts with a second group from a separate one of the polymeric structures in order to cross-link and bond the two polymeric structures together. This bonding and cross-linking increases the molecular weight of the polymer products of the cross-linking reaction and increases the overall linking density of the photoresist. Such an increase in density and linking density helps to improve the resist pattern.

In some embodiments, the cross-linking agent has the following structure:

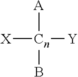

wherein C is carbon, n ranges from 1 to 15; A and B independently include a hydrogen atom, a hydroxyl group, a halide, an aromatic carbon ring, or a straight or cyclic alkyl, alkoxyl/fluoro, alkyl/fluoroalkoxyl chain having a carbon number of between 1 and 12, and each carbon C contains A and B; a first terminal carbon C at a first end of a carbon C chain includes X and a second terminal carbon C at a second end of the carbon chain includes Y, wherein X and Y independently include an amine group, a thiol group, a hydroxyl group, an isopropyl alcohol group, or an isopropyl amine group, except when n=1 then X and Y are bonded to the same carbon C.

Alternatively, instead of or in addition to the cross-linking agent being added to the photoresist composition, a coupling reagent is added in some embodiments, in which the coupling reagent is added in addition to the cross-linking agent. The coupling reagent assists the cross-linking reaction by reacting with the groups on the structure in the polymer resin before the cross-linking reagent, allowing for a reduction in the reaction energy of the cross-linking reaction and an increase in the rate of reaction. The bonded coupling reagent then reacts with the cross-linking agent, thereby coupling the cross-linking agent to the polymer resin.

Alternatively, in some embodiments in which the coupling reagent is added to the photoresist without the cross-linking agent, the coupling reagent is used to couple one group from one of the structures in the polymer resin to a second group from a separate one of the structures in order to cross-link and bond the two polymers together. However, in such an embodiment the coupling reagent, unlike the cross-linking agent, does not remain as part of the polymer, and only assists in bonding one structure directly to another structure.

In some embodiments, the coupling reagent has the following structure:

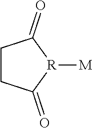

where R is a carbon atom, a nitrogen atom, a sulfur atom, or an oxygen atom; M includes a chlorine atom, a bromine atom, an iodine atom, —NO₂; —SO₃—; —H—; —CN; —NCO, —OCN; —CO₂—; —OH; —OR*, —OC(O)CR*; —SR, —SO₂N(R*)₂; —SO₂R*; SOR; —OC(O)R*; —C(O)OR*; —C(O)R*; —Si(OR*)₃; —Si(R*)₃; epoxy groups, or the like; and R* is a substituted or unsubstituted C1-C12 alkyl, C1-C12 aryl, C1-C12 aralkyl, or the like. Specific examples of materials used as the coupling reagent in some embodiments include the following:

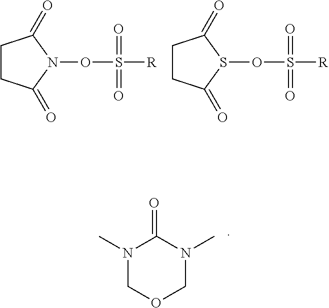

The individual components of the photoresist are placed into a solvent in order to aid in the mixing and dispensing of the photoresist. To aid in the mixing and dispensing of the photoresist, the solvent is chosen at least in part based upon the materials chosen for the polymer resin as well as the PACs. In some embodiments, the solvent is chosen such that the polymer resin and the PACs can be evenly dissolved into the solvent and dispensed upon the layer to be patterned.

In some embodiments, a photoresist includes an organic solvent such as any one or more of ketones, alcohols, polyalcohols, ethers, glycol ethers, cyclic ethers, aromatic hydrocarbons, esters, propionates, lactates, lactic esters, alkylene glycol monoalkyl ethers, alkyl lactates, alkyl alkoxypropionates, cyclic lactones, monoketone compounds that contain a ring, alkylene carbonates, alkyl alkoxyacetate, alkyl pyruvates, lactate esters, ethylene glycol alkyl ether acetates, diethylene glycols, propylene glycol alkyl ether acetates, alkylene glycol alkyl ether esters, alkylene glycol monoalkyl esters, or the like.

Specific examples of materials that may be used as the solvent for the photoresist include any one or more of acetone, methanol, ethanol, toluene, xylene, 4-hydroxy-4-methyl-2-pentatone, tetrahydrofuran, methyl ethyl ketone, cyclohexanone, methyl isoamyl ketone, 2-heptanone, ethylene glycol, ethylene glycol monoacetate, ethylene glycol dimethyl ether, ethylene glycol dimethyl ether, ethylene glycol methylethyl ether, ethylene glycol monoethyl ether, methyl cellosolve acetate, ethyl cellosolve acetate, diethylene glycol, diethylene glycol monoacetate, diethylene glycol monomethyl ether, diethylene glycol diethyl ether, diethylene glycol dimethyl ether, diethylene glycol ethylmethyl ether, diethethylene glycol monoethyl ether, diethylene glycol monobutyl ether, ethyl 2-hydroxypropionate, methyl 2-hydroxy-2-methyl propionate, ethyl 2-hydroxy-2-methylpropionate, ethyl ethoxyacetate, ethyl hydroxyacetate, methyl 2-hydroxy-2-methylbutanate, methyl 3-methoxypropionate, ethyl 3-methoxypropionate, methyl 3-ethoxypropionate, ethyl 3-ethoxypropionate, methyl acetate, ethyl acetate, propyl acetate, butyl acetate, methyl lactate, ethyl lactate, propyl lactate, butyl lactate, propylene glycol, propylene glycol monoacetate, propylene glycol monoethyl ether acetate, propylene glycol monomethyl ether acetate, propylene glycol monopropyl methyl ether acetate, propylene glycol monobutyl ether acetate, propylene glycol monobutyl ether acetate, propylene glycol monomethyl ether propionate, propylene glycol monoethyl ether propionate, propylene glycol methyl ether acetate, propylene glycol ethyl ether acetate, ethylene glycol monomethyl ether acetate, ethylene glycol monoethyl ether acetate, propylene glycol monomethyl ether, propylene glycol monoethyl ether, propylene glycol monopropyl ether, propylene glycol monobutyl ether, ethylene glycol monomethyl ether, ethylene glycol monoethyl ether, ethyl 3-ethoxypropionate, methyl 3-methoxypropionate, methyl 3-ethoxypropionate, ethyl 3-methoxypropionate, β-propiolactone, β-butyrolactone, γ-butyrolactone, α-methyl-γ-butyrolactone, β-methyl-γ-butyrolactone, γ-valerolactone, γ-caprolactone, γ-octanoic lactone, α-hydroxy-γ-butyrolactone, 2-butanone, 3-methylbutanone, pinacolone, 2-pentanone, 3-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexene-2-one, 3-pentene-2-one, cyclopentanone, 2-methylcyclopentanone, 3-methyl cyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethyl cyclohexanone, 2,6-dimethylcyclohexanone, 2,2,6-trimethylcyclohexanone, cycloheptanone, 2-methylcycloheptanone, 3-methylcycloheptanone, propylene carbonate, vinylene carbonate, ethylene carbonate, butylene carbonate, acetate-2-methoxyethyl, acetate-2-ethoxyethyl, acetate-2-(2-ethoxyethoxy)ethyl, acetate-3-methoxy-3-methylbutyl, acetate-1-methoxy-2-propyl, dipropylene glycol, monomethylether, monoethylether, monopropylether, monobutylether, monophenylether, dipropylene glycol monoacetate, dioxane, methyl pyruvate, ethyl pyruvate, propyl pyruvate, methyl methoxypropionate, ethyl ethoxypropionate, n-methylpyrrolidone (NMP), 2-methoxyethyl ether (diglyme), ethylene glycol monomethyl ether, propylene glycol monomethyl ether, methyl propionate, ethyl propionate, ethyl ethoxy propionate, methylethyl ketone, 2-heptanone, cyclopentanone, ethyl 3-ethoxypropionate, propylene glycol methyl ether acetate (PGMEA), methylene cellosolve, 2-ethoxyethanol, N-methylformamide, N,N-dimethylformamide, N-methylformanilide, N-methylacetamide, N,N-dimethylacetamide, dimethylsulfoxide, benzyl ethyl ether, dihexyl ether, acetonylacetone, isophorone, caproic acid, caprylic acid, 1-octanol, 1-nonanol, benzyl alcohol, benzyl acetate, ethyl benzoate, diethyl oxalate, diethyl maleate, phenyl cellosolve acetate, or the like.

As one of ordinary skill in the art will recognize, the materials listed and described above as examples of materials that may be used for the solvent component of the photoresist are merely illustrative and are not intended to limit the embodiments. Rather, any suitable material that dissolves the polymer resin and the PACs may be used to help mix and apply the photoresist. All such materials are fully intended to be included within the scope of the embodiments.

Additionally, while individual ones of the above described materials may be used as the solvent for the photoresist, in other embodiments more than one of the above described materials are used. For example, in some embodiments, the solvent includes a combination mixture of two or more of the materials described. All such combinations are fully intended to be included within the scope of the embodiments.

In addition to the polymer resins, the PACs, the solvents, the cross-linking agent, and the coupling reagent, some embodiments of the photoresist also include a number of other additives that assist the photoresist to obtain high resolution. For example, some embodiments of the photoresist also include surfactants to help improve the ability of the photoresist to coat the surface on which it is applied. In some embodiments, the surfactants include one or more of nonionic surfactants, polymers having fluorinated aliphatic groups, surfactants that contain at least one fluorine atom and/or at least one silicon atom, polyoxyethylene alkyl ethers, polyoxyethylene alkyl aryl ethers, polyoxyethylene-polyoxypropylene block copolymers, sorbitan fatty acid esters, and polyoxyethylene sorbitan fatty acid esters.

Specific examples of materials used as surfactants in some embodiments include one or more of polyoxyethylene lauryl ether, polyoxyethylene stearyl ether, polyoxyethylene cetyl ether, polyoxyethylene oleyl ether, polyoxyethylene octyl phenol ether, polyoxyethylene nonyl phenol ether, sorbitan monolaurate, sorbitan monopalmitate, sorbitan monostearate, sorbitan monooleate, sorbitan trioleate, sorbitan tristearate, polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate, polyethylene glycol distearate, polyethylene glycol dilaurate, polyethylene glycol dilaurate, polyethylene glycol, polypropylene glycol, polyoxyethylenestearyl ether, polyoxyethylene cetyl ether, fluorine containing cationic surfactants, fluorine containing nonionic surfactants, fluorine containing anionic surfactants, cationic surfactants and anionic surfactants, polyoxyethylene cetyl ether, or the like.

Another additive added to some embodiments of the photoresist is a quencher, which inhibits diffusion of the generated acids/bases/free radicals within the photoresist. The quencher improves the resist pattern configuration as well as the stability of the photoresist over time. In an embodiment, the quencher is an amine, such as a second lower aliphatic amine, a tertiary lower aliphatic amine, or the like. Specific examples of amines include one or more of trimethylamine, diethylamine, triethylamine, di-n-propylamine, tri-n-propylamine, tripentylamine, diethanolamine, and triethanolamine, alkanolamine, or the like.

In some embodiments, an organic acid is used as the quencher. In some embodiments, organic acid used as a quencher includes one or more of malonic acid, citric acid, malic acid, succinic acid, benzoic acid, salicylic acid; phosphorous oxo acid and its derivatives, such as phosphoric acid and derivatives thereof such as its esters, phosphoric acid di-n-butyl ester and phosphoric acid diphenyl ester; phosphonic acid and derivatives thereof such as its ester, such as phosphonic acid dimethyl ester, phosphonic acid di-n-butyl ester, phenylphosphonic acid, phosphonic acid diphenyl ester, and phosphonic acid dibenzyl ester; and phosphinic acid and derivatives thereof such as its esters, including phenylphosphinic acid.

Another additive added to some embodiments of the photoresist is a stabilizer, which assists in preventing undesired diffusion of the acids generated during exposure of the photoresist. In some embodiments, the stabilizer includes one or more nitrogenous compounds. In some embodiments, a stabilizer includes one or more of aliphatic primary, secondary, and tertiary amines; cyclic amines, including piperidines, pyrrolidines, morpholines; aromatic heterocycles, including pyridines, pyrimidines, purines; imines, including diazabicycloundecene, guanidines, imides, amides, or the like. In some embodiments, ammonium salts are used for the stabilizer. In some embodiments, a stabilizer incudes one or more of ammonium, primary, secondary, tertiary, and quaternary alkyl- and aryl-ammonium salts of alkoxides, including hydroxide, phenolates, carboxylates, aryl and alkyl sulfonates, sulfonamides, or the like. Other cationic nitrogenous compounds, including pyridinium salts and salts of other heterocyclic nitrogenous compounds with anions, such as alkoxides, including hydroxide, phenolates, carboxylates, aryl and alkyl sulfonates, sulfonamides, or the like, are used in some embodiments.

Another additive in some embodiments of the photoresist is a dissolution inhibitor to help control the dissolution of the photoresist during development. In an embodiment, bile-salt esters are used as the dissolution inhibitor. Specific examples of dissolution inhibitors in some embodiments include one or more of cholic acid, deoxycholic acid, lithocholic acid, t-butyl deoxycholate, t-butyl lithocholate, and t-butyl-3-acetyl lithocholate.

Another additive in some embodiments of the photoresist is a plasticizer. Plasticizers may be used to reduce delamination and cracking between the photoresist and underlying layers (e.g., the layer to be patterned). Plasticizers include one or more of monomeric, oligomeric, and polymeric plasticizers, such as oligo- and polyethyleneglycol ethers, cycloaliphatic esters, and non-acid reactive steroidaly-derived materials. Specific examples of materials used for the plasticizer in some embodiments include one or more of dioctyl phthalate, didodecyl phthalate, triethylene glycol dicaprylate, dimethyl glycol phthalate, tricresyl phosphate, dioctyl adipate, dibutyl sebacate, triacetyl glycerine, or the like.

A coloring agent is another additive included in some embodiments of the photoresist. The coloring agent observers examine the photoresist and find any defects that may need to be remedied prior to further processing. In some embodiments, the coloring agent is a triarylmethane dye or a fine particle organic pigment. In some embodiment, a coloring agent includes one or more of crystal violet, methyl violet, ethyl violet, oil blue #603, Victoria Pure Blue BOH, malachite green, diamond green, phthalocyanine pigments, azo pigments, carbon black, titanium oxide, brilliant green dye (C. I. 42020), Victoria Pure Blue FGA (Linebrow), Victoria BO (Linebrow) (C. I. 42595), Victoria Blue BO (C. I. 44045), rhodamine 6G (C. I. 45160), benzophenone compounds, such as 2,4-dihydroxybenzophenone and 2,2′,4,4′-tetrahydroxybenzophenone; salicylic acid compounds, such as phenyl salicylate and 4-t-butylphenyl salicylate; phenylacrylate compounds, such as ethyl-2-cyano-3,3-diphenylacrylate, and 2′-ethylhexyl-2-cyano-3,3-diphenylacrylate; benzotriazole compounds, such as 2-(2-hydroxy-5-methylphenyl)-2H-benzotriazole, and 2-(3-t-butyl-2-hydroxy-5-methylphenyl)-5-chloro-2H-benzotriazole; coumarin compounds, such as 4-methyl-7-diethylamino-1-benzopyran-2-one; thioxanthone compounds, such as diethylthioxanthone; stilbene compounds, naphthalic acid compounds, azo dyes, phthalocyanine blue, phthalocyanine green, iodine green, Victoria blue, crystal violet, titanium oxide, naphthalene black, Photopia methyl violet, bromphenol blue and bromcresol green; laser dyes, such as Rhodamine G6, Coumarin 500, DCM (4-(dicyanomethylene)-2-methyl-6-(4-dimethylaminostyryl)-4H pyran)), Kiton Red 620, Pyrromethene 580, or the like. One or more coloring agents may be used in combination to provide the desired coloring.

Adhesion additives are added to some embodiments of the photoresist to promote adhesion between the photoresist and an underlying layer upon which the photoresist has been applied (e.g., the layer to be patterned). In some embodiments, the adhesion additives include one or more of a silane compound with at least one reactive substituent such as a carboxyl group, a methacryloyl group, an isocyanate group and/or an epoxy group. In some embodiments, a the adhesion components includes one or more of trimethoxysilyl benzoic acid, γ-methacryloxy propyl trimethoxy silane, vinyltriacetoxysilane, vinyltrimethoxysilane, γ-isocyanatepropyl triethoxy silane, γ-glycidoxypropyl trimethoxy silane, β-(3,4-epoxycyclohexyl) ethyl trimethoxy silane, benzimidazoles and polybenzimidazoles, a lower hydroxyalkyl substituted pyridine derivative, a nitrogen heterocyclic compound, urea, thiourea, an organophosphorus compound, 8-oxyquinoline, 4-hydroxypteridine and derivatives, 1,10-phenanthroline and derivatives, 2,2′-bipyridine and derivatives, benzotriazoles, organophosphorus compounds, phenylenediamine compounds, 2-amino-1-phenylethanol, N-phenylethanolamine, N-ethyldiethanolamine, N-ethylethanolamine and derivatives, benzothiazole, and a benzothiazoleamine salt having a cyclohexyl ring and a morpholine ring, 3-glycidoxypropyltrimethoxysilane, 3-glycidoxypropyl triethoxysilane, 3-mercaptopropyl trimethoxysilane, 3-mercaptopropyltriethoxysilane, 3-methacryloyloxy propyltrimethoxysilane, vinyl trimethoxysilane, or the like.

Metal oxide nanoparticles are added to some embodiments of the photoresist. In some embodiments, the photoresist includes one or more metal oxides nanoparticles selected from the group consisting of titanium dioxide, zinc oxide, zirconium dioxide, nickel oxide, cobalt oxide, manganese oxide, copper oxides, iron oxides, strontium titanate, tungsten oxides, vanadium oxides, chromium oxides, tin oxides, hafnium oxide, indium oxide, cadmium oxide, molybdenum oxide, tantalum oxides, niobium oxide, aluminum oxide, and combinations thereof. In some embodiments, metal oxide nanoparticles have an average particle diameter between 1 and 100 nm.

Surface leveling agents are added to some embodiments of the photoresist to assist a top surface of the photoresist to be level, so that impinging light will not be adversely modified by an unlevel surface. In some embodiments, surface leveling agents include one or more of fluoroaliphatic esters, hydroxyl terminated fluorinated polyethers, fluorinated ethylene glycol polymers, silicones, acrylic polymer leveling agents, or the like.

In some embodiments, the polymer resin and the PACs, along with any desired additives or other agents, are added to the solvent for application. Once added, the mixture is then mixed in order to achieve a homogenous composition throughout the photoresist to ensure that there are no defects caused by uneven mixing or non-homogenous composition of the photoresist. Once mixed together, the photoresist may either be stored prior to its usage or used immediately.

Once ready, the photoresist is applied onto the layer to be patterned, as shown in FIG. 2, such as the substrate 10 to form a photoresist layer 15. In some embodiments, the operation P110 of resist coating includes applying the photoresist using a process such as a spin-on coating process, a dip coating method, an air-knife coating method, a curtain coating method, a wire-bar coating method, a gravure coating method, a lamination method, an extrusion coating method, combinations of these, or the like. In some embodiments, the photoresist layer 15 thickness ranges from about 10 nm to about 300 nm.

In some embodiments, a photoresist layer is made from a photoresist composition including a first compound or a first precursor and a second compound or a second precursor combined in a vapor state. In some embodiments, the first precursor or first compound is an organometallic having a formula: MₐR_{b}X_{c}, where M is at least one of Sn, Bi, Sb, In, Te, Ti, Zr, Hf, V, Co, Mo, W, Al, Ga, Si, Ge, P, As, Y, La, Ce, or Lu; and R is a substituted or unsubstituted alkyl, alkenyl, or carboxylate group. In some embodiments, M is selected from the group consisting of Sn, Bi, Sb, In, Te, and combinations thereof. In some embodiments, R is a C3-C6 alkyl, alkenyl, or carboxylate. In some embodiments, R is selected from the group consisting of propyl, isopropyl, butyl, iso-butyl, sec-butyl, tert-butyl, pentyl, isopentyl, sec-pentyl, tert-pentyl, hexyl, iso-hexyl, sec-hexyl, tert-hexyl, and combinations thereof. X is a ligand, ion, or other moiety, which is reactive with the second compound or second precursor; and 1≤a≤2, b≥1, c≥1, and b+c≤5 in some embodiments. In some embodiments, the alkyl, alkenyl, or carboxylate group is substituted with one or more fluoro groups. In some embodiments, the organometallic precursor is a dimer where each monomer unit is linked by an amine group. In some embodiments, R is alkyl, such as CₙH₂ₙ₊₁ where n≥3. In some embodiments, R is fluorinated, e.g., having the formula CₙFₓH₍₂ₙ₊₁₎₋ₓ₎. In some embodiments, R has at least one beta-hydrogen or beta-fluorine. In some embodiments, R is selected from the group consisting of i-propyl, n-propyl, t-butyl, i-butyl, n-butyl, sec-butyl, n-pentyl, i-pentyl, t-pentyl, and sec-pentyl, and combinations thereof.

In some embodiments, X is any moiety readily displaced by the second compound or second precursor to generate an M-OH moiety, such as a moiety selected from the group consisting of amines, including dialkylamino and monalkylamino; alkoxy; carboxylates, halogens, and sulfonates. In some embodiments, the sulfonate group is substituted with one or more amine groups. In some embodiments, the halide is one or more selected from the group consisting of F, Cl, Br, and I. In some embodiments, the sulfonate group includes a substituted or unsubstituted C1-C3 group.

In some embodiments, the first organometallic compound or first organometallic precursor includes a metallic core W with ligands L attached to the metallic core M+. In some embodiments, the metallic core M+ is a metal oxide. The ligands L include C3-C12 aliphatic or aromatic groups in some embodiments. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C3-C12 aliphatic or aromatic groups include heterocyclic groups. In some embodiments, the C3-C12 aliphatic or aromatic groups are attached to the metal by an ether or ester linkage. In some embodiments, the C3-C12 aliphatic or aromatic groups include nitrite and sulfonate substituents.

In some embodiments, the organometallic precursor or organometallic compound include a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl tris(dimethylamino) tin, n-propyl tris(diethylamino) tin, and analogous alkyl tris(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy) tin, t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl tris(dimethylamino) tin, or n-propyl tris(butoxy) tin. In some embodiments, the organometallic precursors or organometallic compounds are fluorinated. In some embodiments, the organometallic precursors or compounds have a boiling point less than about 200° C.

In some embodiments, the first compound or first precursor includes one or more unsaturated bonds that can be coordinated with a functional group, such as a hydroxyl group, on the surface of the substrate or an intervening underlayer to improve adhesion of the photoresist layer to the substrate or underlayer.

In some embodiments, the second precursor or second compound is at least one of an amine, a borane, a phosphine, or water. In some embodiments, the amine has a formula NpHnXm, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BpHnXm, where 0≤n≤3, 0≤m≤3, n+m=3 when p is 1, and n+m=4 when p is 2, and each X is independently a halogen selected from the group consisting of F, Cl, Br, and I. In some embodiments, the phosphine has a formula PpHnXm, where 0≤n≤3, 0≤m≤3, n+m=3, when p is 1, or n+m=4 when p is 2, and each X is independently a halogen selected from the group consisting of F, Cl, Br, and I.

In some embodiments, the second precursor or compound is water, ammonia, or hydrazine. The reaction product of the water, ammonia, or hydrazine and the organometallic precursor or compound may form hydrogen bonds that increase the boiling point of the reaction product and prevent emission of the metal photoresist material, thereby preventing metal contamination. The hydrogen bonds can also help prevent moisture effects to the photoresist layer quality.

In some embodiments, the operation P110 of resist coating a photoresist composition on a substrate where the photoresist includes first and second precursors or compounds is performed by a vapor phase deposition operation. In some embodiments, the vapor phase deposition operation includes atomic layer deposition (ALD) or chemical vapor deposition (CVD). In some embodiments, the ALD includes plasma-enhanced atomic layer deposition (PE-ALD), and the CVD includes plasma-enhanced chemical vapor deposition (PE-CVD), metal-organic chemical vapor deposition (MO-CVD), atmospheric pressure chemical vapor deposition (AP-CVD), and low pressure chemical vapor deposition (LP-CVD).

After the photoresist layer 15 has been applied to the substrate 10, a pre-bake of the photoresist layer is performed in some embodiments to cure and dry the photoresist prior to radiation exposure (see FIG. 1). The curing and drying of the photoresist layer 15 can remove a solvent component while leaving behind the polymer resin and any other selected components such as the PACs, the cross-linking agent, and the other chosen additives. In some embodiments, the pre-baking is performed at a temperature suitable to evaporate the solvent, such as between about 50° C. and 250° C., although the precise temperature depends upon the materials chosen for the photoresist. The pre-baking is performed for a time sufficient to cure and dry the photoresist layer, such as between about 10 seconds to about 10 minutes.

FIG. 3 illustrates a selective exposure of the photoresist layer to form an exposed region 50 and an unexposed region 15. In some embodiments, the exposure to radiation is carried out by placing the photoresist coated substrate in a photolithography tool. The photolithography tool includes a photomask 30, optics, an exposure radiation source to provide the radiation 45 for exposure, and a movable stage for supporting and moving the substrate under the exposure radiation.

In some embodiments, the radiation source (not shown) supplies radiation 45, such as ultraviolet light, to the photoresist layer 15 in order to induce a reaction of the PACs, which in turn reacts with the polymer resin to chemically alter those regions of the photoresist layer to which the radiation 45 impinges. In some embodiments the radiation is electromagnetic radiation, such as g-line (wavelength of about 436 nm), i-line (wavelength of about 365 nm), ultraviolet radiation, deep ultraviolet radiation, extreme ultraviolet, electron beams, or the like. In some embodiments, the radiation source is selected from the group consisting of a mercury vapor lamp, xenon lamp, carbon arc lamp, a KrF excimer laser light (wavelength of 248 nm), an ArF excimer laser light (wavelength of 193 nm), an F₂ excimer laser light (wavelength of 157 nm), or a CO₂ laser-excited Sn plasma (extreme ultraviolet, wavelength of 13.5 nm).

In some embodiments, optics (not shown) are used in the photolithography tool to expand, reflect, or otherwise control the radiation before or after the radiation 45 is patterned by the photomask 30. In some embodiments the optics include one or more lenses, mirrors, filters, and combinations thereof to control the radiation 45 along its path.

In an embodiment, the patterned radiation 45 is extreme ultraviolet light having a 13.5 nm wavelength, the PAC is a photoacid generator, the group to be decomposed is a carboxylic acid group on the structure, and a cross linking agent is used. The patterned radiation 45 impinges upon the photoacid generator, the photoacid generator absorbs the impinging patterned radiation 45. This absorption initiates the photoacid generator to generate a proton (e.g., a H+ atom) within the photoresist layer 15. When the proton impacts the carboxylic acid group on the structure, the proton reacts with the carboxylic acid group, chemically altering the carboxylic acid group and altering the properties of the polymer resin in general. The carboxylic acid group then reacts with the cross-linking agent to cross-link with other polymer resins within the exposed region of the photoresist layer 15.

In some embodiments, the exposure of the photoresist layer 15 uses an immersion lithography technique. In such a technique, an immersion medium (not shown) is placed between the final optics and the photoresist layer, and the exposure radiation 45 passes through the immersion medium.

After the photoresist layer 15 has been exposed to the exposure radiation 45, a post-exposure baking is performed in some embodiments to assist in the generating, dispersing, and reacting of the acid/base/free radical generated from the impingement of the radiation 45 upon the PACs during the exposure. Such thermal assistance helps to create or enhance chemical reactions which generate chemical differences between the exposed region 50 and the unexposed region 52 within the photoresist layer 15. These chemical differences also cause differences in the solubility between the exposed region 50 and the unexposed region 52. In some embodiments, the post-exposure baking occurs at temperatures ranging from about 50° C. to about 160° C. for a period of between about 20 seconds and about 120 seconds.

The inclusion of the cross-linking agent into the chemical reactions helps the components of the polymer resin (e.g., the individual polymers) react and bond with each other, increasing the molecular weight of the bonded polymer in some embodiments. In particular, an initial polymer has a side chain with a carboxylic acid protected by one of the groups to be removed/acid labile groups.

In some forms, a polymer of a photoresist includes a protecting group that forms part of an ester through a bond to the ester oxygen of the ester group, the ester oxygen being the oxygen atom bonded to the carbon atom of a carbonyl group of the ester group. In some embodiments, a photoresist includes polymers including any one or more protecting groups of methyl, ethyl, propyl, C4-C10 alkyl, tert-butyl, methyl adamantyl, methyl cyclopentyl, methyl cyclohexyl, ethyl cyclopentyl, ethyl cyclohexyl, isopropyl cyclopentyl, isopropyl cyclohexyl, tert-butoxycarbonyl, iso-norbornyl, 2-methyl-2-adamantyl, 2-ethyl-2-adamantyl, 3-methyl tetrahydrofuran, 2-methyl tetrahydrofuran, lactone, 2-methyl tetrahydropyran, benzyl, and a C3-C14 aromatic group.

In some embodiments, the acid labile or protecting groups to be removed are removed in a de-protecting reaction, which is initiated by a proton H+ generated by a photoacid generator during either the exposure process or during the post-exposure baking process. The H+ first removes the groups to be removed, e.g., acid labile group/protecting group, and another hydrogen atom may replace the removed structure to form a de-protected polymer. Once de-protected, a cross-linking reaction occurs between two separate de-protected polymers that have undergone the de-protecting reaction and the cross-linking agent in a cross-linking reaction. In particular, hydrogen atoms within the carboxylic groups formed by the de-protecting reaction are removed and the oxygen atoms react with and bond with the cross-linking agent. This bonding of the cross-linking agent to two polymers bonds the two polymers not only to the cross-linking agent but also bonds the two polymers to each other through the cross-linking agent, thereby forming a cross-linked polymer.

In some embodiments, the amount of photoacid generator and/or cross-linking agent in a photoresist can be adjusted to retain residual carboxylic acid groups and/or deprotected ester groups in a patterned photoresist layer so that a coating composition including a block copolymer including a mesogenic structure can bond to the patterned photoresist by reacting with the carboxylic acid groups or deprotected ester groups. In some embodiments, a photoacid generator is included in a photoresist in an abundance and the amount of cross-linking agent is limited to ensure that residual carboxylic acid groups and/or deprotected ester groups are retained in a patterned photoresist layer.

In some embodiments, by increasing the molecular weight of the polymers through the cross-linking reaction, the cross-linked polymer becomes less soluble in organic solvent negative resist developers. In other embodiments, photoresist developers dissolve the cross-linked, radiation-exposed portions of the photoresist layer. In some embodiments, the photoresist developer includes a major solvent, an acid or a base, and a chelate. In some embodiments, the concentration of the major solvent is from about 60 wt. % to about 99 wt. % based on the total weight of the photoresist developer. The acid or base concentration is from about 0.001 wt. % to about 20 wt. % based on the total weight of the photoresist developer. In certain embodiments, the acid or base concentration in the developer is from about 0.01 wt. % to about 15 wt. % based on the total weight of the photoresist developer. The chelate concentration is from about 0.001 wt. % to about 20 wt. % of the total weight of the photoresist developer. In certain embodiments, the concentration of the chelate ranges from about 0.01 wt. % to about 15 wt. % based on the total weight of the photoresist developer.

In some embodiments, suitable acids for the photoresist developer 57 include one or more organic acids. In some embodiments, the photoresist developer 57 includes one or more of ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, oxalic acid, maleic acid, carbonic acid, oxoethanoic acid, 2-hydroxyethanoic acid, propanedioic acid, butanedioic acid, 3-oxobutanoic acid, hydroxylamine-o-sulfonic acid, formamidinesulfinic acid, methylsulfamic acid, sulfoacetic acid, 1,1,2,2-tetrafluoroethanesulfonic acid, 1,3-propanedisulfonic acid, nonafluorobutane-1-sulfonic acid, 5-sulfosalicylic acid, or the like. In some embodiments, suitable acids for the photoresist developer 57 include one or more inorganic acids. In some embodiments a photoresist developer includes 57 one or more of nitric acid, sulfuric acid, hydrochloric acid, and the like.

In some embodiments, suitable bases for the photoresist developer 57 include one or more organic bases and inorganic bases. In some embodiments a photoresist developer includes one or more of monoethanolamine, monoisopropanolamine, 2-amino-2-methyl-1-propanol, 1H-benzotriazole, 1,2,4-triazole, 1,8-diazabicycloundec-7-ene, tetrabutylammonium hydroxide, tetramethylammonium hydroxide, ammonium hydroxide, ammonium sulfamate, ammonium carbamate, tetraethylammonium hydroxide, tetrapropylammonium hydroxide, and the like.

In some embodiments, the chelate includes one or more of ethylenediaminetetraacetic acid (EDTA), ethylenediamine-N,N′-disuccinic acid (EDDS), diethylenetriaminepentaacetic acid (DTPA), polyaspartic acid, trans-1,2-cyclohexanediamine-N,N,N′,N′-tetraacetic acid monohydrate, ethylenediamine, and the like.

In an embodiment, the photoresist developer 57 includes an additional solvent. In some embodiments, the additional solvent includes one or more of water, hexane, heptane, octane, toluene, xylene, dichloromethane, chloroform, carbon tetrachloride, trichloroethylene, and like hydrocarbon solvents; critical carbon dioxide, methanol, ethanol, propanol, butanol, and like alcohol solvents; diethyl ether, dipropyl ether, dibutyl ether, ethyl vinyl ether, dioxane, propylene oxide, tetrahydrofuran, cellosolve, methyl cellosolve, butyl cellosolve, methyl carbitol, diethylene glycol monoethyl ether and like ether solvents; acetone, methyl ethyl ketone, methyl isobutyl ketone, isophorone, cyclohexanone and like ketone solvents; methyl acetate, ethyl acetate, propyl acetate, butyl acetate and like ester solvents; pyridine, formamide, and N,N-dimethyl formamide or the like. In an embodiment, the concentration of the additional solvent is from about 1 wt. % to about 40 wt. % based on the total weight of the developer.

In some embodiments, the photoresist developer 57 includes hydrogen peroxide in a concentration of up to about 10 wt. % based on the total weight of the developer.

In some embodiments, the photoresist developer 57 includes up to about 1 wt. % of a surfactant to increase the solubility and reduce the surface tension on the substrate. In some embodiments, the surfactant includes one or more of alkylbenzenesulfonates, lignin sulfonates, fatty alcohol ethoxylates, and alkylphenol ethoxylates. In some embodiments, the surfactant is selected from the group consisting of sodium stearate, 4-(5-dodecyl)benzenesulfonate, ammonium lauryl sulfate, sodium lauryl sulfate, sodium laureth sulfate, sodium myreth sulfate, dioctyl sodium sulfosuccinate, perfluorooctanesulfonate, perfluorobutanesulfonate, alkyl-aryl ether phosphate, alkyl ether phosphates, sodium lauroyl sarcosinate, perfluorononanoate, perfluorooctanoate, octenidine dihydrochloride, cetrimonium bromide, cetylpyridinium chloride, benzalkonium chloride, benzethonium chloride, dimethyldioctadecylammonium chloride, dioctadecyldimethylammonium bromide, 3-[(3-cholamidopropyl)dimethylammonio]-1-propanesulfonate, cocamidopropyl hydroxysultaine, cocamidopropyl betaine, phospholipidsphosphatidylserine, phosphatidylethanolamine, phosphatidylcholine, sphingomyelins, octaethylene glycol monodecyl ether, pentaethylene glycol monodecyl ether, polyethoxylated tallow amine, cocamide monoethanolamine, cocamide diethanolamine, glycerol monostearate, glycerol monolaurate, sorbitan monolaurate, sorbitan monostearate, sorbitan tristearate, and the like.

In some embodiments, the developer 57 is applied to the photoresist layer 15 using a spin-on process. In the spin-on process, the developer 57 is applied to the photoresist layer 15 from above the photoresist layer 15 while the photoresist coated substrate is rotated, as shown in FIG. 4. In some embodiments the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 10° C. and about 80° C. The development operation continues for between about 30 seconds to about 10 minutes in some embodiments.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

According to an embodiment, during the developing operation P150, the developer 57 dissolves the radiation exposed regions 50 of the cross-linked negative resist, exposing the surface of the substrate 10, as shown in FIG. 5A, and leaving behind unexposed photoresist regions 52. After the developing operation, remaining developer is removed from the patterned photoresist covered substrate. The remaining developer is removed using a spin-dry process in some embodiments, although any suitable removal technique may be used. After the photoresist layer 15 is developed, the remaining developer is removed.

According to an embodiment, an operation of P160 depositing a coating composition on a patterned structure of a photoresist resist layer is performed. In some embodiments, the operation P160 depositing a coating film includes a spin-on coating process, a dip coating method, an air-knife coating method, a curtain coating method, combinations of these, or the like. In an embodiment of utilizing the spin-on process, the coating composition 60 is applied to the patterned photoresist layer 15 from a dispenser 67 above the patterned photoresist layer while the substrate is rotated, as shown in FIG. 5B. The coating composition 60 conformally coats the sidewalls within openings 55 as well as other surfaces of the patterned photoresist layer 15.

In some embodiments, the coating composition contains one or more block copolymers including a first moiety configured to chemically bond with the patterned surface of a photoresist layer and a second moiety including a mesogenic structure. In some forms, the first moiety of block copolymer includes a group capable of reacting with any one or more of a carboxylic acid group, a deprotected ester group, or a hydroxyl group on the patterned surface of the photoresist layer. In some embodiments, the first moiety includes one or more of an ether group, a hydroxyl group, a carboxylic acid group, an ester group, an amine group, a nitrite group, an anhydride group, or an amide group. In some embodiments, the first moiety includes the amine group, and the amine group is a primary amine group, a secondary amine group, or a tertiary amine group.

In some embodiments, the first moiety reacts with a carboxylic acid group or deprotected ester group of the photoresist formed by a photoacid generator present in the photoresist during either the exposure operation or the post-exposure baking operation. In some embodiments, where the patterned surface of a photoresist includes an ester group including a protecting group, a dehydration reaction is performed on the patterned surface to remove the protecting group from the ester group. The deprotected ester group can react with the first moiety of the block copolymer. In some embodiments, performing the dehydration reaction includes applying an acid to the patterned surface before applying the coating composition. In some embodiments, performing the dehydration reaction includes applying the coating composition including an acid to the patterned surface so that the acid deprotects the ester groups on the patterned surface. In some embodiments, performing the dehydration reaction includes applying an acid to the patterned surface after applying the coating composition so that the acid penetrates or is otherwise transported through the coating composition and deprotects the ester groups on the patterned surface. Embodiments of acid useful for dehydration reactions include sulfuric acid, hydrofluoric acid, and nitric acid.

In some embodiments, a mesogenic structure of the second moiety of the block copolymer has a property of exhibiting liquid crystal alignment upon curing the coating composition. Upon curing the mesogenic structures of polymers in the coating composition can align and smooth irregularities in the patterned surface of the photoresist layer. The cured coating can also provide a hardened surface to the patterned photoresist layer. The smoothed and/or hardened surface can improve performance when using the patterned photoresist layer as an etching mask during an etching operation.

In some embodiments, the coating composition or coating film formed thereby includes a block copolymer having a structure of formula (I):

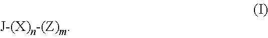

In some embodiments, the J moiety of formula (I) corresponds to the first moiety of the block copolymer and includes any group capable of reacting with and bonding to a patterned photoresist layer. In some embodiments, the J moiety includes a group capable of reacting with any one or more of a carboxylic acid group, a deprotected ester group, or a hydroxyl group on the patterned surface of the photoresist layer. In some embodiments, J includes one or more of an ether group, a hydroxyl group, a carboxylic acid group, an ester group, an amine group, a nitrite group, an anhydride group, or an amide group. In some embodiments, the Z moiety of formula (I) includes a mesogenic group and corresponds to the second moiety of the block copolymer.

In some embodiments, X in formula (I) is a linking group. In some forms, a linking group includes one or more of a long alkyl chain such as a C5 to C50 chain, a C10 to C40 chain, a C20 to C30 chain, an ester group, a carboxylic acid group, or an amine group. In some embodiments, the linking group provides a space between the mesogenic structure of the second moiety and a location where the first moiety reacts with the patterned photoresist to provide flexibility, permit the mesogenic structure to exhibit liquid crystal alignment, and permit the block copolymer to self-assemble on the patterned photoresist layer. In some embodiments, the linking group X includes one or more of an C1-C30 alkyl group, a poly(meth)acrylic acid group, an ester group, an amine group, a group of formula (II), and a group of formula (III):

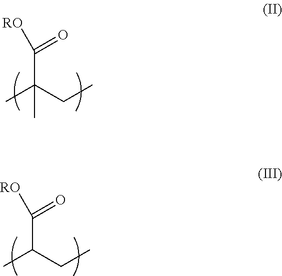

wherein R in formulas (II) and (III) is a C1-C6 alkyl group, a C1-C6 cycloalkyl group, or a C6-C14 aromatic group.

In some embodiments, a second moiety of a block copolymer or unit Z of formula (I) includes one or more of following structures groups (IV)-(VII) including a mesogenic structure:

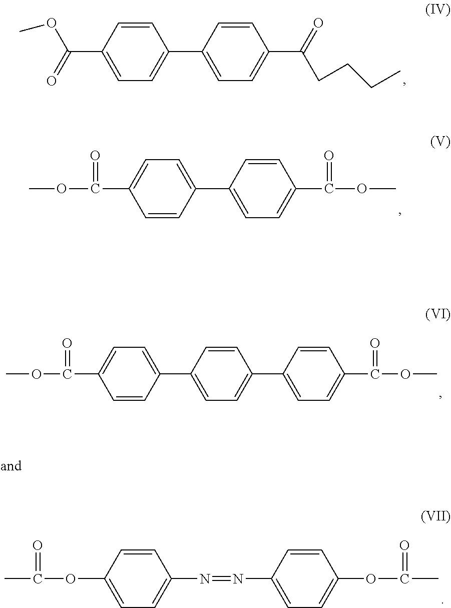

In some embodiments, the value of n in formula (I) ranges from 1 to 100, and the value of m ranges from 1 to 1000. The values of n and m can be adjusted based on the pitch of the pattern formed on a photoresist layer. In some forms, the value of n is adjusted depending on a pitch of a patterned photoresist so as to provide the block copolymer with desired flexibility to permit alignment of the mesogenic moiety. In some forms, the value of m is also adjusted based on the pitch of a patterned photoresist to permit self-assembly of the block copolymer on the surface of the patterned photoresist. In some forms, the block copolymer has a polydispersity (PDI=Mw/Mn) of 1.1 or less, where Mw is the weight average molecular weight and Mn is the number average molecular weight.

In some embodiments of a block copolymer of a coating composition, the block copolymer has the following formula:

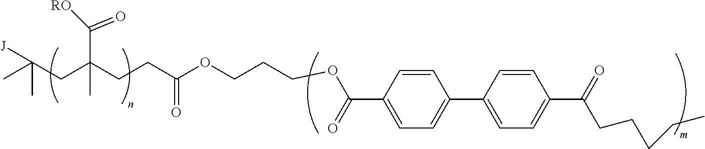

wherein J includes an ether group, a hydroxyl group, a carboxylic acid group, an ester group, an amine group, a nitrite group, an anhydride group, or an amide group, R is a C1-C6 alkyl group, a C1-C6 cycloalkyl group, or a C3-C14 aromatic group, n ranges from 1 to 100, and m ranges from 1 to 1000.

The coating composition in cured form can provide improved hardness relative to an uncoated patterned photoresist layer. It is believed that alignment of aromatic moieties having mesogenic properties improves the hardness of the pattern relative to an uncoated patterned photoresist having carbonyl-type structures exposed on the surface thereof. The improved hardness of the cured coating can improve the etch rate of the coated patterned photoresist layer relative to the etching performance of an uncoated patterned photoresist layer. Also, improved smoothness imparted to the patterned photoresist layer by the cured coating can improve the precision of structures formed during the etching operation using the coated patterned photoresist layer as an etching mask.

In some forms, the coating composition further includes one or more solvents. In some embodiments, the coating composition includes one or more organic solvents. In some embodiments, the coating composition includes one or more non-polar solvents. In some embodiments, a non-polar solvent is considered to be a solvent having a Snyder's polarity index (P′) of about 3.5 or less, about 3.1 or less, about 3.0 or less, about 2.5 or less, about 2.0 or less, about 1.5 or less, about 1.5 or less, or about 0.5 or less. In some embodiments, any one or more of the non-polar solvents described herein for use in a photoresist are included in a coating composition. Mesogenic structures that exhibit liquid crystal behavior are typically organic molecules that can dissolve in non-polar solvents, whereas some photoresist structures will not substantially dissolve in non-polar solvents. In other words, a sufficiently non-polar solvent can dissolve mesogenic structures of a block copolymer but will avoid dissolving a photoresist pattern upon application coating composition. In some embodiments, the solvent includes one or more of dichloromethane, diethyl ether, o-dichlorobenzene, chlorobenze, o-xylene, p-xylene, methyl t-butyl ether, toluene, benzene, n-butyl chloride, cyclohexane, petroleum ether, iso-octane, hexane, heptane, cyclopentane, 1,1,2-trichlorofluoroethane, and pentane.

A layer or film of the coating composition can be conformally deposited on the patterned photoresist layer at any useful thickness. In some embodiments, the coating composition is applied at a thickness up to about 1000 angstroms (Å). In some embodiments, the coating composition is applied at a thickness greater than 1000 Å. In some embodiments the coating composition is applied at a thickness ranging from about 50 Å up to about 1000 Å. The thickness of the applied coating composition can be tailored to the pitch of a pattern in the photoresist. The thickness of the applied coating composition can be adjusted by adjusting the relative amounts of solvent and block copolymer present in the coating composition, with higher proportions of solvent relative to block copolymer reducing viscosity of the coating composition and lower proportions of solvent relative to block copolymer increasing viscosity. In some embodiments, the viscosity of the coating composition to be applied to a patterned photoresist ranges from about 1 centipoise (cP) to about 5 cP.

In some embodiments, as shown in FIGS. 1 and 5C, an operation P170 of curing the coating composition 60 deposited on the patterned photoresist layer 15 is performed to form a cured coating 64 on the patterned photoresist layer. In some embodiments, the curing the coating composition includes baking the coating composition at a temperature ranging from about 20° C. to about 150° C. for a time sufficient to cure the coating composition to a state that mesogenic structures in the copolymer exhibit liquid crystal alignment. In some embodiments, curing of the coating composition includes exposing the coating composition to light having a wavelength of 100 nm to 800 nm for a time sufficient to cure the coating composition to a state that mesogenic structures in the copolymer exhibit liquid crystal alignment. In some embodiments, curing the coating composition includes exposing the coating composition to a magnetic field at an applied strength and time sufficient to cure the coating composition to a state that mesogenic structures in the copolymer exhibit liquid crystal alignment. In some embodiments, curing the coating composition includes exposing the coating composition to a plasma at an applied voltage and time sufficient to cure the coating composition to a state that mesogenic structures in the copolymer exhibit liquid crystal alignment.

In some embodiments, the coating composition is dried to remove solvent before or after curing the coating composition on the patterned photoresist layer. In some embodiments, the drying is conducted at a temperature ranging from about 25° C. to about 75° C. for about 5 minutes to about 10 minutes.

FIG. 5D schematically illustrates the cured coating composition 64 including a plurality of block copolymers 70 self-assembled on a patterned surface of a photoresist layer 15. The first moieties of the block copolymers 70 are bonded to the carboxylic acid or deprotected ester groups 17. Photoresist reactive units 19 of the block copolymers 70 include the first moiety bonded to the photoresist layer and part of a linking group. Liquid crystal units 21 are attached to the linking groups and include mesogenic structures exhibiting liquid crystal alignment. Upon curing the coating composition, region 23 of the block copolymers provides a flexible phase, and region 25 provides a liquid crystal phase imparting improved smoothness and/or hardness to the patterned photoresist. An etching operation using the cured coating composition provides structures having desired LCDU in some embodiments.

In some embodiments, as shown in FIGS. 1 and 6, the method includes an operation P180 of etching a substrate 10 using the patterned photoresist layer 15 coated with the cured coating composition 64 as an etching mask. For example, an etching operation, using dry or wet etching, is performed in some embodiments, to transfer the pattern of openings 55 of the photoresist layer 15 to the underlying substrate 10 and form corresponding recesses 55′. The substrate 10 has a different etch resistance than the photoresist layer 15 covered with the cured coating composition 64. In some embodiments, the etchant is more selective to the substrate 10 than the photoresist layer 15 covered with the cured coating composition 64.

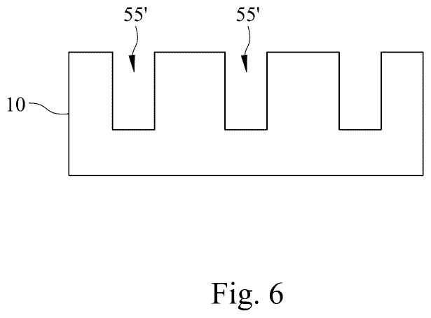

In some embodiments, a layer to be patterned 60 is disposed over the substrate prior to forming the photoresist layer, as shown in FIG. 7. In some embodiments, the layer to be patterned 60 is a metallization layer or a dielectric layer, such as a passivation layer, disposed over a metallization layer. In embodiments where the layer to be patterned 60 is a metallization layer, the layer to be patterned 60 is formed of a conductive material using metallization processes, and metal deposition techniques, including chemical vapor deposition, atomic layer deposition, and physical vapor deposition (e.g.—sputtering). Likewise, if the layer to be patterned 60 is a dielectric layer, the layer to be patterned 60 is formed by dielectric layer formation techniques, including thermal oxidation, chemical vapor deposition, atomic layer deposition, and physical vapor deposition.

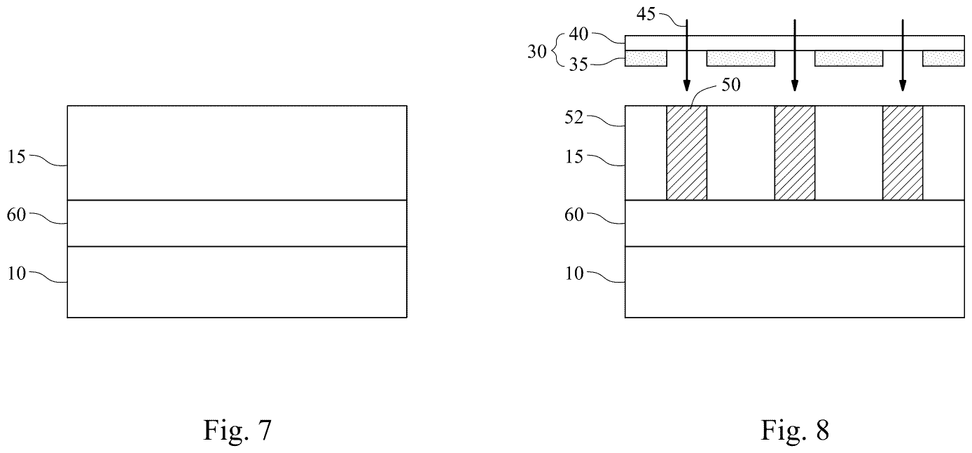

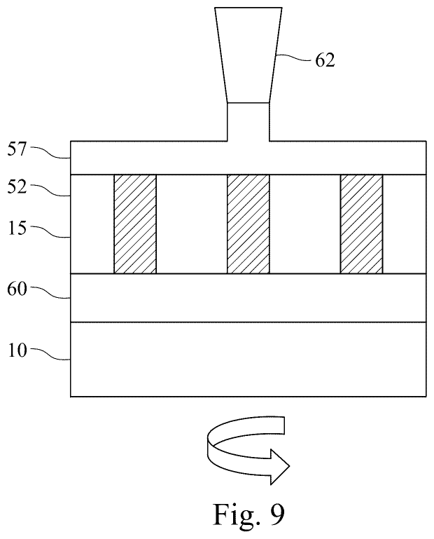

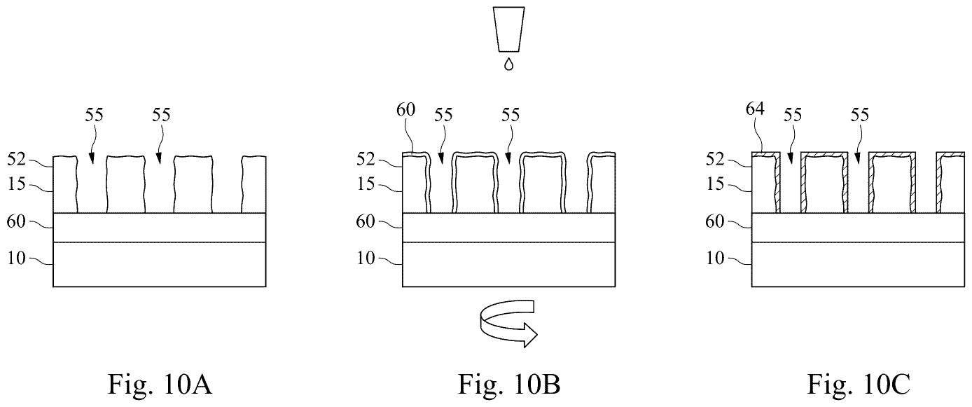

The photoresist layer 15 is subsequently selectively exposed to actinic radiation 45 to form exposed regions 50 and unexposed regions 52 in the photoresist layer, as shown in FIG. 8, and described herein in relation to FIG. 3. In the embodiment shown in FIG. 8, the photoresist is a negative photoresist, wherein polymer crosslinking occurs in the exposed regions 50 in some embodiments. As shown in FIG. 9, the exposed photoresist regions 50 are developed by dispensing developer 57 from a dispenser 62 to form a pattern of photoresist openings 55, as shown in FIG. 10A. The development operation is similar to that explained with reference to FIGS. 4 and 5, herein.

FIG. 10B illustrates an embodiment after applying a coating 60 containing a copolymer including a liquid crystal moiety to the photoresist layer 15 shown in FIG. 10A. FIG. 10C illustrates an embodiment including a cured coating 64 formed by curing the coating 60 shown in FIG. 10B. As shown in FIG. 10C, the cured coating 64 forms smooth surfaces over the photoresist layer 15 within the openings 55, as also illustrated FIG. 5C.

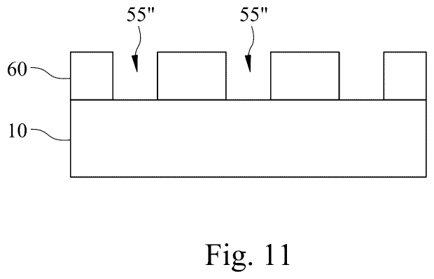

As shown in FIG. 11, the pattern 55 in the photoresist layer 15 is transferred to the layer to be patterned 60 using an etching operation and the photoresist layer is removed, as explained with reference to FIG. 6 to form pattern 55″ in the layer to be patterned 60.

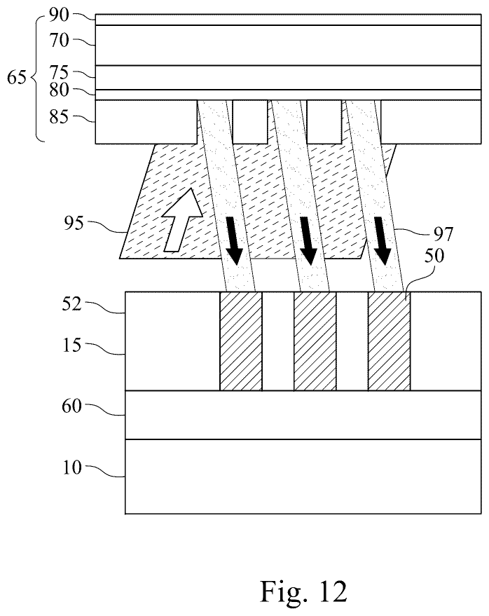

In some embodiments, the selective exposure of the photoresist layer 15 to form exposed regions 50 and unexposed regions 52 is performed using extreme ultraviolet lithography. In an extreme ultraviolet lithography operation, a reflective photomask 65 is used to form the patterned exposure light, as shown in FIG. 12. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist coated substrate 10, while the portion of the extreme ultraviolet radiation incident upon the absorber 85 is absorbed by the photomask. In some embodiments, additional optics, including mirrors are between the reflective photomask 65 and the photoresist coated substrate.

A coating composition according to embodiments of the disclosure serves to improve the etching performance of a patterned photoresist layer. Cured forms of the coating composition increase the hardness and/or smoothness of surfaces of the patterned photoresist layer in embodiments of the disclosure. The increased hardness improves the etching rate achievable with the patterned photoresist and the improved smoothness improves the precision of structures formed when using the patterned photoresist as an etching mask.

According to an embodiment, a method of manufacturing a semiconductor device includes depositing a coating composition on a patterned surface of a photoresist layer. The photoresist layer is disposed over a substrate. The coating composition includes a block copolymer including a first moiety configured to chemically bond with the patterned surface and a second moiety including a mesogenic structure. The method further includes curing the coating composition deposited on the patterned surface of the photoresist layer. In an embodiment, the coating composition further includes a non-polar solvent. In an embodiment, the depositing the coating composition on the patterned surface includes performing a spin-on coating operation applying the coating composition to the patterned surface. In an embodiment, the first moiety of the block copolymer chemically bonds with the patterned surface by reacting with a carboxylic acid group or a hydroxyl group on the patterned surface. In an embodiment, the patterned surface includes an ester group including a protecting group, and the method further includes performing a dehydration reaction to deprotect the ester group and reacting the deprotected ester group and the first moiety of the block copolymer. In an embodiment, the protecting group is any of methyl, ethyl, propyl, C4-C10 alkyl, tert-butyl, methyl adamantyl, methyl cyclopentyl, methyl cyclohexyl, ethyl cyclopentyl, ethyl cyclohexyl, isopropyl cyclopentyl, isopropyl cyclohexyl, tert-butoxycarbonyl, iso-norbornyl, 2-methyl-2-adamantyl, 2-ethyl-2-adamantyl, 3-methyl tetrahydrofuran, 2-methyl tetrahydrofuran, lactone, 2-methyl tetrahydropyran, benzyl, and a C3-C14 aromatic group. In an embodiment, the performing the dehydration reaction includes applying an acid to the patterned surface having the coating composition thereon. In an embodiment, the first moiety includes one or more of an ether group, a hydroxyl group, a carboxylic acid group, an ester group, an amine group, a nitrite group, an anhydride group, and an amide group. In an embodiment, the first moiety includes the amine group, and the amine group is a primary amine group, a secondary amine group, or a tertiary amine group. In an embodiment, the method further includes performing an etching operation using the photoresist layer as an etching mask after curing the coating composition on the patterned surface. In an embodiment, the etching operation forms a pattern in a layer disposed between the substrate and the patterned photoresist layer. In an embodiment, the block copolymer has a structure according to the following formula:

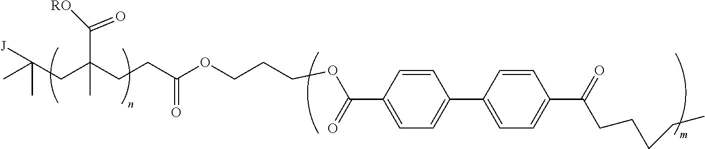

wherein J includes an ether group, a hydroxyl group, a carboxylic acid group, an ester group, an amine group, a nitrite group, an anhydride group, or an amide group, R is a C1-C6 alkyl group, a C1-C6 cycloalkyl group, or a C3-C14 aromatic group, n ranges from 1 to 100, and m ranges from 1 to 1000.

According to another embodiment, a method of manufacturing a semiconductor device includes depositing a coating film over a photoresist layer, the photoresist layer including a patterned structure including openings; and curing the coating film on the photoresist layer. The coating film includes a block copolymer having a structure of formula (I):

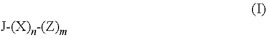

wherein J includes an ether group, a hydroxyl group, a carboxylic acid group, an ester group, an amine group, a nitrite group, an anhydride group, or an amide group, X is linking group, Z includes a mesogenic group, n ranges from 1 to 100, and m ranges from 1 to 1000. In an embodiment, the linking group X includes one or more of an C1-C30 alkyl group, a poly(meth)acrylic acid group, an ester group, an amine group, a group of formula (II), and a group of formula (III):

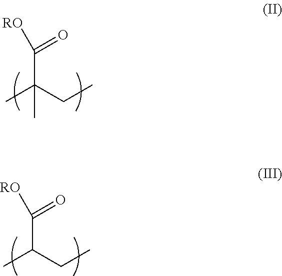

wherein R in formulas (II) and (III) is a C1-C6 alkyl group, a C1-C6 cycloalkyl group, or a C6-C14 aromatic group. In an embodiment, the mesogenic group Z includes one or more of the following groups (IV)-(VII):

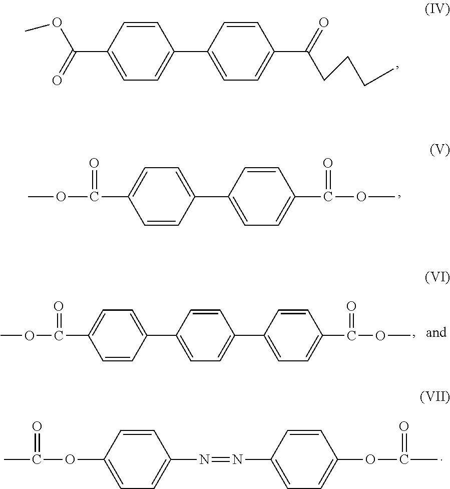

In an embodiment, depositing the coating film includes performing a spin-on coating operation applying the coating film to the photoresist layer.

According to another embodiment, a method of manufacturing a semiconductor device includes coating a wafer with a photoresist layer; exposing the photoresist layer to a pattern of actinic radiation; developing the exposed photoresist layer to form a patterned photoresist layer; depositing a coating composition on the patterned photoresist layer. The coating composition includes a block copolymer including a first moiety configured to chemically bond with the patterned photoresist layer and second moiety including a mesogenic structure; and curing the coating composition deposited on the patterned photoresist layer. In an embodiment, the curing of the coating composition includes baking the coating composition at a temperature ranging from 20° C. to 150° C. for 1 to 10 minutes. In an embodiment, the curing of the coating composition includes exposing the coating composition to light having a wavelength of 100 nm to 800 nm. In an embodiment, the curing of the coating composition includes exposing the coating composition to a magnetic field. In an embodiment, the curing of the coating composition includes exposing the coating composition to a plasma in a plasma treating apparatus. In an embodiment, the block copolymer has a structure of formula (I):

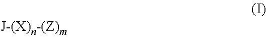

wherein J is the first moiety and includes an ether group, a hydroxyl group, a carboxylic acid group, an ester group, an amine group, a nitrite group, an anhydride group, or an amide group, X is a linking group, Z is the second moiety and includes the mesogenic structure, n ranges from 1 to 100, and m ranges from 1 to 1000.

According to another embodiment, a composition for coating a patterned photoresist includes a block copolymer including a first moiety configured to chemically bond to the patterned photoresist, and a second moiety including a mesogenic group; and a non-polar solvent. In an embodiment, the first moiety of the block copolymer is configured to chemically bond with the patterned photoresist by reacting with a carboxylic acid group or a hydroxyl group of the patterned photoresist. In an embodiment, the first moiety of the block copolymer is configured to chemically bond with the patterned photoresist by reacting with an ester group of the patterned photoresist upon deprotection of the ester group. In an embodiment, the first moiety includes one or more of an ether group, a hydroxyl group, a carboxylic acid group, an ester group, an amine group, a nitrite group, an anhydride group, and an amide group. In an embodiment, the first moiety includes the amine group, and the amine group is a primary amine group, a secondary amine group, or a tertiary amine group. In an embodiment, the mesogenic group includes one or more of the following groups (IV)-(VII):

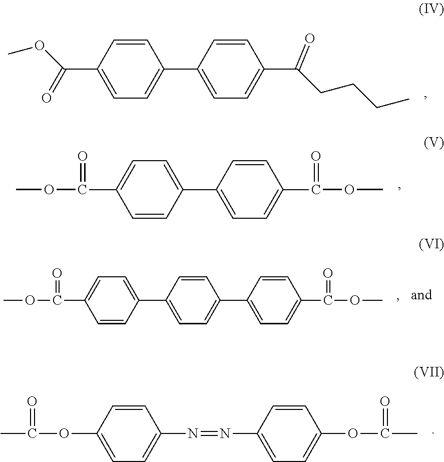

In an embodiment, the block copolymer has the following formula:

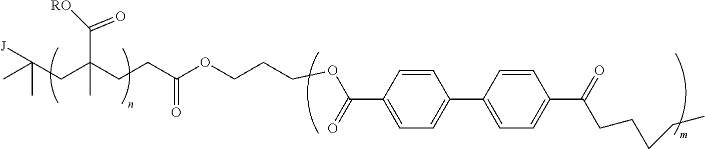

wherein J is an ether group, a hydroxyl group, a carboxylic acid group, an ester group, an amine group, a nitrite group, an anhydride group, or an amide group, R is a C1-C6 alkyl group, a C1-C6 cycloalkyl group, or a C3-C14 aromatic group, n ranges from 1 to 100, and m ranges from 1 to 1000.

According to another embodiment, a photoresist resolution enhancement composition includes a solvent; and a block copolymer having a structure of formula (I):

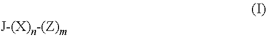

wherein J includes an ether group, a hydroxyl group, a carboxylic acid group, an ester group, an amine group, a nitrite group, an anhydride group, or an amide group, X is linking group, Z includes a mesogenic group, n ranges from 1 to 100, and m ranges from 1 to 1000. In an embodiment, the linking group X includes one or more of an C1-C10 alkyl group, a poly(meth)acrylic acid group, an ester group, an amine group, a group of formula (II), and a group of formula (III):

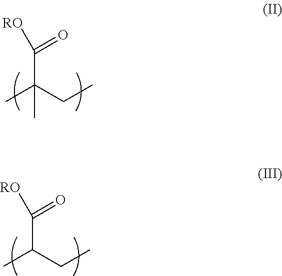

wherein R in formulas (II) and (III) is a C1-C6 alkyl group, a C1-C6 cycloalkyl group, or a C6-C14 aromatic group. In an embodiment, the mesogenic group Z includes one or more of the following structures (IV)-(VII):

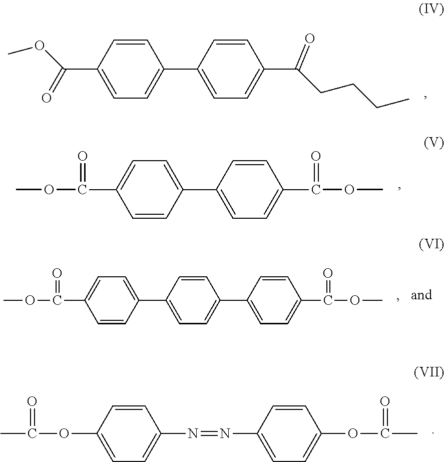

In an embodiment, the solvent is non-polar. In an embodiment, the solvent includes one or more of dichloromethane, diethyl ether, o-dichlorobenzene, chlorobenze, o-xylene, p-xylene, methyl t-butyl ether, toluene, benzene, n-butyl chloride, cyclohexane, petroleum ether, iso-octane, hexane, heptane, cyclopentane, 1,1,2-trichlorofluoroethane, and pentane.

According to another embodiment, a patterned photoresist coating composition includes a block copolymer including a first moiety configured to chemically bond with a patterned photoresist and a second moiety including a mesogenic structure. In an embodiment, the block copolymer has a structure of formula (I):

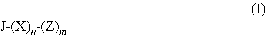

wherein J is the first moiety and includes an ether group, a hydroxyl group, a carboxylic acid group, an ester group, an amine group, a nitrite group, an anhydride group, or an amide group, X is a linking group, Z is the second moiety including the mesogenic structure, n ranges from 1 to 100, and m ranges from 1 to 1000. In an embodiment, the the block copolymer has a polydispersity of 1.1 or less. In an embodiment, the second moiety Z includes one or more of the following structures (IV)-(VII):

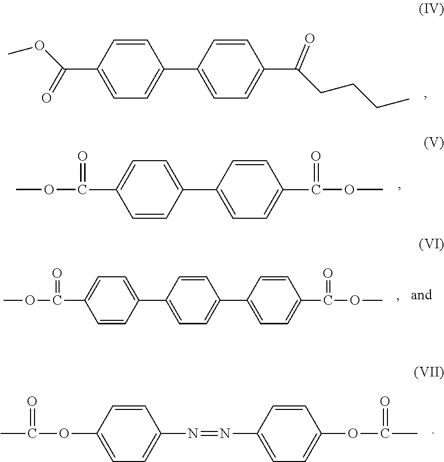

In an embodiment, the composition further includes a solvent. In an embodiment, the solvent is non-polar. In an embodiment, the solvent includes one or more of dichloromethane, diethyl ether, o-dichlorobenzene, chlorobenze, o-xylene, p-xylene, methyl t-butyl ether, toluene, benzene, n-butyl chloride, cyclohexane, petroleum ether, iso-octane, hexane, heptane, cyclopentane, 1,1,2-trichlorofluoroethane, and pentane. In an embodiment, the linking group X includes one or more of an C1-C30 alkyl group, a poly(meth)acrylic acid group, an ester group, an amine group, a group of formula (II), and a group of formula (III):

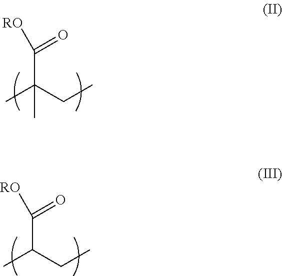

wherein R in formulas (II) and (III) is a C1-C6 alkyl group, a C1-C6 cycloalkyl group, or a C6-C14 aromatic group. In an embodiment, the first moiety includes one or more of an ether group, a hydroxyl group, a carboxylic acid group, an ester group, an amine group, a nitrite group, an anhydride group, and an amide group.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
depositing a coating composition on a patterned surface of a photoresist layer, wherein the photoresist layer is disposed over a substrate, and the coating composition comprises a block copolymer including a first moiety configured to chemically bond with the patterned surface and a second moiety including a mesogenic structure; and
curing the coating composition deposited on the patterned surface of the photoresist layer.

2. The method of claim 1, wherein the coating composition further comprises a non-polar solvent.

3. The method of claim 1, wherein the depositing the coating composition on the patterned surface includes performing a spin-on coating operation applying the coating composition to the patterned surface.

4. The method of claim 1, wherein the first moiety of the block copolymer chemically bonds with the patterned surface by reacting with a carboxylic acid group or a hydroxyl group on the patterned surface.

5. The method of claim 1, wherein the patterned surface comprises an ester group including a protecting group, and the method further comprises performing a dehydration reaction to deprotect the ester group and reacting the deprotected ester group and the first moiety of the block copolymer.

6. The method of claim 5, wherein the protecting group is any of methyl, ethyl, propyl, C4-C10 alkyl, tert-butyl, methyl adamantyl, methyl cyclopentyl, methyl cyclohexyl, ethyl cyclopentyl, ethyl cyclohexyl, isopropyl cyclopentyl, isopropyl cyclohexyl, tert-butoxycarbonyl, iso-norbornyl, 2-methyl-2-adamantyl, 2-ethyl-2-adamantyl, 3-methyl tetrahydrofuran, 2-methyl tetrahydrofuran, a lactone, 2-methyl tetrahydropyran, benzyl, and a C3-C14 aromatic group.

7. The method of claim 5, wherein the performing the dehydration reaction includes applying an acid to the patterned surface having the coating composition thereon.

8. The method of claim 1, wherein the first moiety includes one or more of an ether group, a hydroxyl group, a carboxylic acid group, an ester group, an amine group, a nitrite group, an anhydride group, and an amide group.

9. The method of claim 8, wherein the first moiety includes the amine group, and the amine group is a primary amine group, a secondary amine group, or a tertiary amine group.

10. The method of claim 1, further comprising performing an etching operation using the photoresist layer as an etching mask after curing the coating composition on the patterned surface.

11. The method of claim 10, wherein the etching operation forms a pattern in a layer disposed between the substrate and the patterned photoresist layer.

12. The method of claim 1, wherein the block copolymer has a structure according to the following formula: 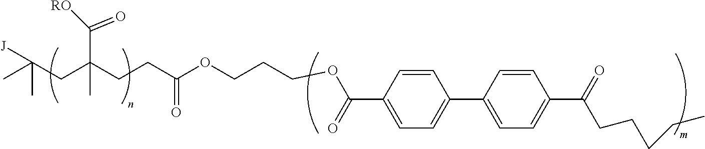
wherein J includes an ether group, a hydroxyl group, a carboxylic acid group, an ester group, an amine group, a nitrite group, an anhydride group, or an amide group,
R is a C1-C6 alkyl group, a C1-C6 cycloalkyl group, or a C3-C14 aromatic group,
n ranges from 1 to 100, and
m ranges from 1 to 1000.

13. A method of manufacturing a semiconductor device, the method comprising:
depositing a coating film over a photoresist layer, the photoresist layer including a patterned structure including openings; and
curing the coating film on the photoresist layer,
wherein the coating film includes a block copolymer having a structure of formula (I): 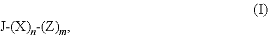
wherein J includes an ether group, a hydroxyl group, a carboxylic acid group, an ester group, an amine group, a nitrite group, an anhydride group, or an amide group,
X is linking group,
Z includes a mesogenic group,
n ranges from 1 to 100, and
m ranges from 1 to 1000.

14. The method of claim 13, wherein the linking group X includes one or more of an C1-C30 alkyl group, a poly(meth)acrylic acid group, an ester group, an amine group, a group of formula (II), and a group of formula (III): 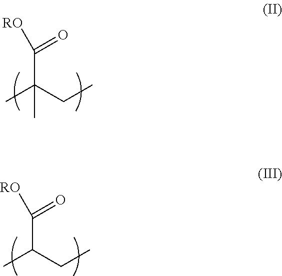
wherein R in formulas (II) and (III) is a C1-C6 alkyl group, a C1-C6 cycloalkyl group, or a C6-C14 aromatic group.

15. The method of claim 13, wherein the mesogenic group Z includes one or more of the following groups (IV)-(VII):

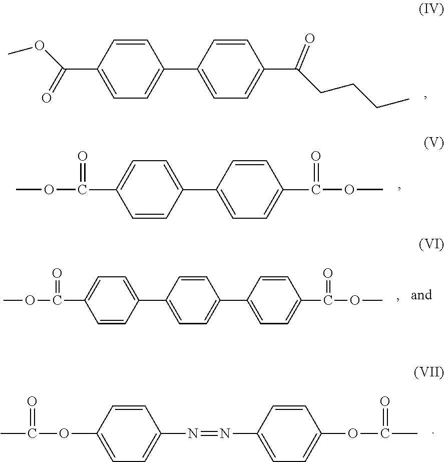

16. The method of claim 13, wherein depositing the coating film includes performing a spin-on coating operation applying the coating film to the photoresist layer.

17. A composition for coating a patterned photoresist, the composition comprising:
a block copolymer including a first moiety configured to chemically bond to the patterned photoresist, and a second moiety including a mesogenic group; and
a non-polar solvent.

18. The composition of claim 17, wherein the first moiety includes one or more of an ether group, a hydroxyl group, a carboxylic acid group, an ester group, an amine group, a nitrite group, an anhydride group, and an amide group.

19. The composition of claim 18, wherein the first moiety includes the amine group, and the amine group is a primary amine group, a secondary amine group, or a tertiary amine group.

20. The composition of claim 18, wherein the mesogenic group includes one or more of the following groups (IV)-(VII): [chemical structure]
